(19) United States
(12) Patent Application Publication
(10) Pub. No.: US 2024/0186443 A1
(43) Pub. Date: Jun. 6, 2024

(54) SOLAR MODULE DARKENING PROCESS

(71) Applicant: MAXEON SOLAR PTE. LTD., Singapore (SG)

(72) Inventor: Paul ADRIANI, Fremont, CA (US)

(73) Assignee: MAXEON SOLAR PTE. LTD., Singapore (SG)

(21) Appl. No.: 18/525,415

(22) Filed: Nov. 30, 2023

Related U.S. Application Data
(60) Provisional application No. 63/429,860, filed on Dec. 2, 2022.

(51) Int. Cl. H01L 31/18

(52) U.S. Cl. CPC H01L 31/186

(57) ABSTRACT

A solar cell module with darkened metallic components is disclosed. A method of darkening the visible metallic components of the solar cells of a solar cell module is disclosed. The method creates a dark patina on the metallic components of a solar cell.

### CROSS REFERENCE TO RELATED APPLICATIONS

This application claims benefit of priority to U.S. Provisional Patent Application No. 63/429,860 filed Dec. 2, 2022, which is incorporated herein by reference in its entirety.

### FIELD OF THE INVENTION

The invention relates generally to solar cell modules or panels and the solar cells within the solar cell modules.

### BACKGROUND

Concerns regarding global warming have accelerated the embrace of renewable energy resources. One example of renewable energy is solar.

The rooftops of residential buildings can offer a desirable location for the placement of photovoltaic (PV) solar modules for harvesting solar energy. However, for residential rooftop solar module installations, aesthetics can be a consideration for the homeowner.

Specifically, a uniformly dark appearance may be considered visually superior to solar modules having mixed colors. Such mixed coloration can arise from the presence of white backsheets visible between solar cells, and/or shiny frames, wires, ribbons, solder, solder pads, and/or fingers.

### BRIEF DESCRIPTION OF THE DRAWINGS

The figures described below depict various aspects of the system and methods disclosed herein. Each figure depicts an embodiment of a particular aspect of the disclosed system and methods, and that each of the figures is intended to accord with a possible embodiment thereof. Further, wherever possible, the following description refers to the reference numerals included in the following figures, in which features depicted in multiple figures are designated with consistent reference numerals.

FIG. 1 shows a portion of the front side of a solar cell.

FIG. 2 shows a portion of the back side of a solar cell.

FIG. 3 shows a portion of the front side of a solar cell.

FIG. 4 shows a portion of the back side of a solar cell.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

Embodiments relate to solar modules and fabrication processes, which darken metal to result in a more uniform appearance. In particular, non-dark solar module components can be selectively darkened by exposure to specific environmental condition(s), which may be present in the gas and/or liquid phase(s).

Once PV cells are manufactured, darkening through exposure to reactive environmental condition(s) in the form of gas and/or liquid, may be performed at or between any step up to a module lamination step.

One possible approach is to darken appearance following layout of a PV cell matrix. According to specific embodiments, the cell matrix may comprise PV cells that are arranged in a series string, which may (but need not be) an overlapping, shingled configuration.

According to certain embodiments, the cell matrix may be darkened in one step by exposure to a global source.

Alternatively, darkening may be accomplished through relative motion between the cell matrix and a local source. This can take the form of moving the cell matrix past a linear source, and/or rastering a small-area source over the cell matrix.

Another possible time of performing a darkening process, may be following creation of a cell string. Again, this could occur all at once, from a linear source, and/or using a small-area source.

Still another possible time for performing a darkening process, is after creation of an individual PV cell. This could occur all at once, from a linear source, and/or using a small area source.

The environmental condition(s) to which the cell is exposed, may comprise a variety of reactive gas(es) and/or liquid(s). For example, one metallic component of a solar module may comprise silver material (e.g., a silver conducting finger).

Accordingly, particular embodiments may employ an ozone gas generator and silver reacting at an optimized concentration/time/temperature combination to form dark silver oxide on the surface. Waste ozone may be converted to harmless oxygen.

Some embodiments could employ reactive conditions comprising hydrogen peroxide (e.g., in aqueous or gas form) to react with silver at an optimized concentration/time/temperature combination to form dark silver oxide on the surface. Waste hydrogen peroxide can be converted to water and O₂.

Still other embodiments could employ reactive conditions comprising halogen(s)—e.g., chlorine—in order to form a halide. For example, a resulting silver chloride may desirably exhibit a dark color.

Certain embodiments could utilize exposure to reactive conditions in the form of sulfur. One approach could employ a hydrogen sulfide gas source, to form dark silver sulfide. The speed of the reaction may be influenced by the sulfur concentration and temperature.

Moreover, Liver of Sulfur is an aqueous liquid or gel comprising a mixture of potassium sulfide, potassium polysulfide, potassium thiosulfate, and also possibly potassium bisulfide. Exposure of silver or copper to Liver of Sulfur can result in the formation of a black patina on copper or silver. One example of Liver of Sulfur is the XLGEL available from THE BEADSMITH of Carteret, New Jersey.

It is noted that exposure to a plurality of environmental conditions, could take place in sequence.

It is also noted that reaction under a specific environmental condition could be affected by one or more factors. One is the concentration of sulfur/chlorine/hydrogen peroxide/ozone. Another is the composition of the metal material, including any surface plating.

Still another potential factor affecting a darkening reaction to the environmental conditions, could be the application of an external electrical circuit, imposing a positive or negative electrical voltage, or allowing electrons to travel between the electrodes of the circuit. Examples can include but are not limited to electroplating, battery charging, and battery discharging.

Silver/silver chloride may be a reference electrode in electrochemical measurements. That silver chloride is black in color. Silver chloride can be formed chemically by electroplating in concentrated hydrochloric acid. Silver chloride can be formed electrochemically by oxidizing the silver in a chloride solution, where the silver is the anode in the electrochemical reaction.

Similarly, silver/silver oxide may be an electrode in batteries. Again, that silver oxide is black in color.

Also similarly, silver/silver sulfide may be an electrode in electrochemical measurements. Again, that silver sulfide is black in color.

Embodiments could employ a multi-step process. For a liquid-based process, this could comprise (optional) cell cleaning, exposure to the reactive conditions, exposure to neutralizing conditions, rising, and drying. The cleaning may be optional, as the matrix/string/cell is already manufactured under clean conditions.

### Example

In this example, bifacial cells were exposed to environmental conditions comprising sulfur. Specifically, full size PV cells (M10-size, 182 mm square) were exposed to the following environmental conditions: 10 seconds in a 45° C. solution of 1 drop of the XLGEL commercial patina gel per 50 ml of distilled water.

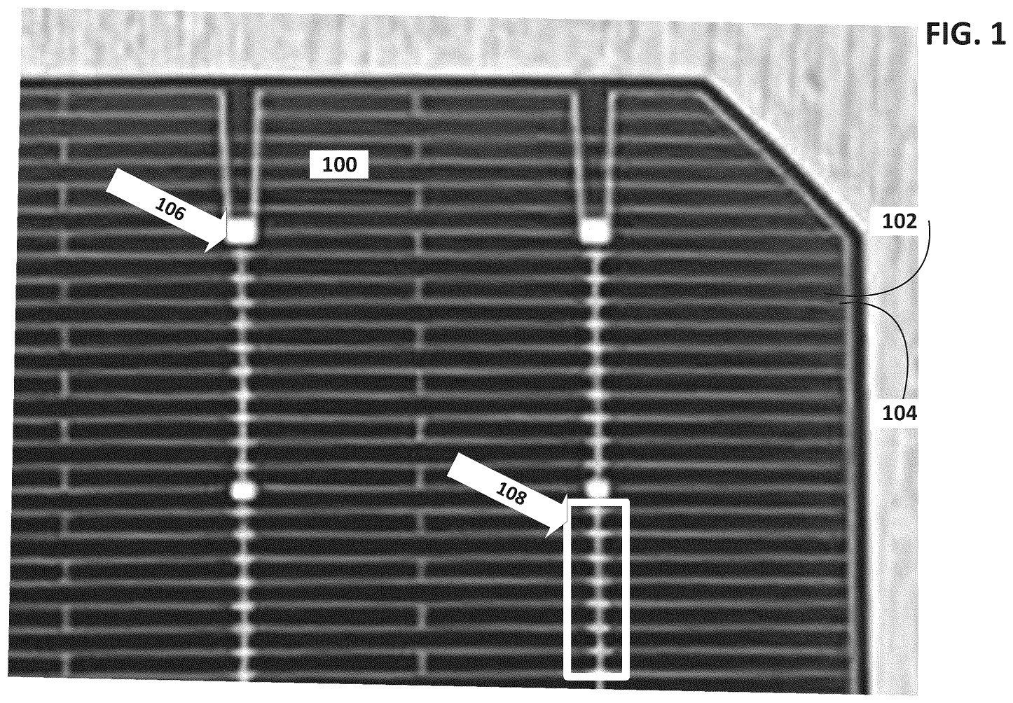

FIG. 1 shows a portion of a front side of a reference bifacial cell 100 without exposure. Visually contrasting against the dark PV material 102, is the shiny color exhibited by silver conductive fingers 104 having a width of about 50 μm. An example current collection region 108 connects the fingers to the solder pads 106.

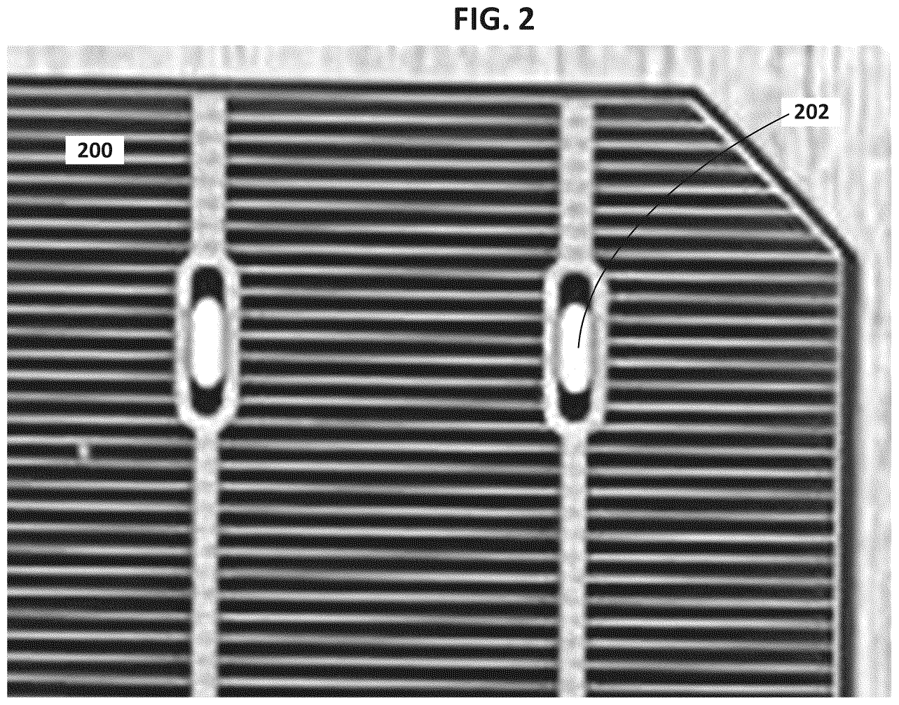

FIG. 2 shows a back side of a reference bifacial cell prior to exposure.

The cell is a half-cut cell that is designed to be connected into strings with solder-coated copper wires. Those wires are soldered to the frontside pads 106 of one cell and the backside pads 202 of an adjacent cell. The frontside solder pads and the backside solder pads each comprise silver to facilitate the soldering of the copper wires to the pads.

The remaining backside metal pattern is aluminum-based. That backside metal pattern is designed to make good electrical contact to the PV cell backside and to have reduced cost compared to silver.

Also, metallization shadowing effects on the backside of the PV cell have smaller effect on module power output compared to metallization shadowing effects on the frontside of the PV cell. This may be because the backside only receives a fraction of the sunlight intensity compared to the front side. When the front side is receiving sunlight, the backside might be receiving between 0% and 40% relative intensity of that sunlight, depending on the details of the solar installation on a rooftop or on a ground mount.

The lower backside power contribution means that the most cost-effective backside metallization patterns tend to have less expensive materials, higher electrical resistivity, thicker line widths, coarser patterns, and higher percentage of shadowing.

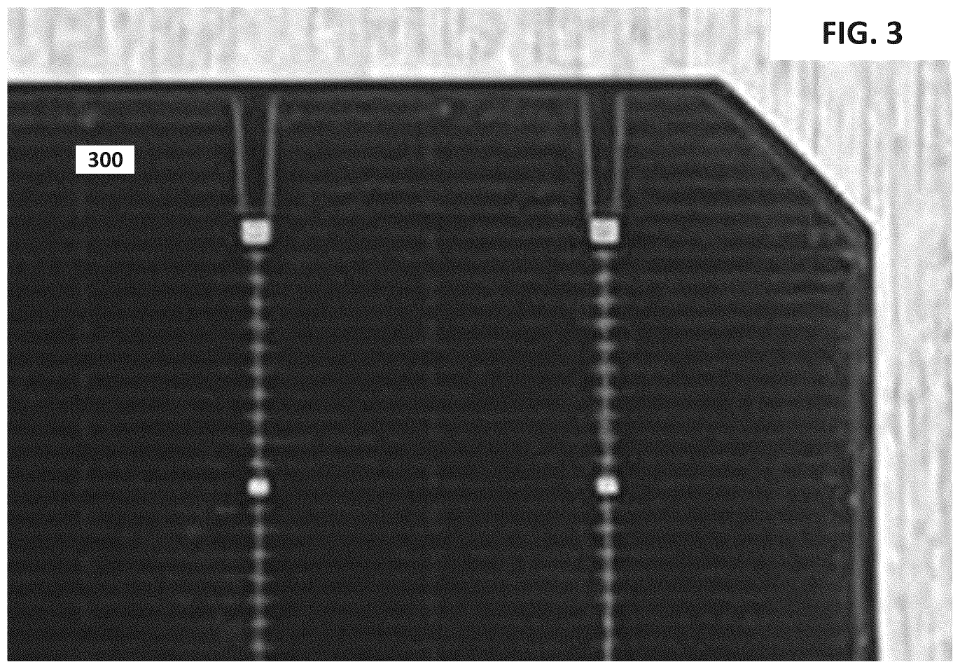

FIG. 3 shows the front side of a bifacial cell following exposure to sulfur. The silver fingers are substantially darkened, leading to a more homogenous black appearance for the front side. Also the current collection regions are significantly darkened, and solder pads are slightly darkened, thereby further contributing to uniform visual appeal.

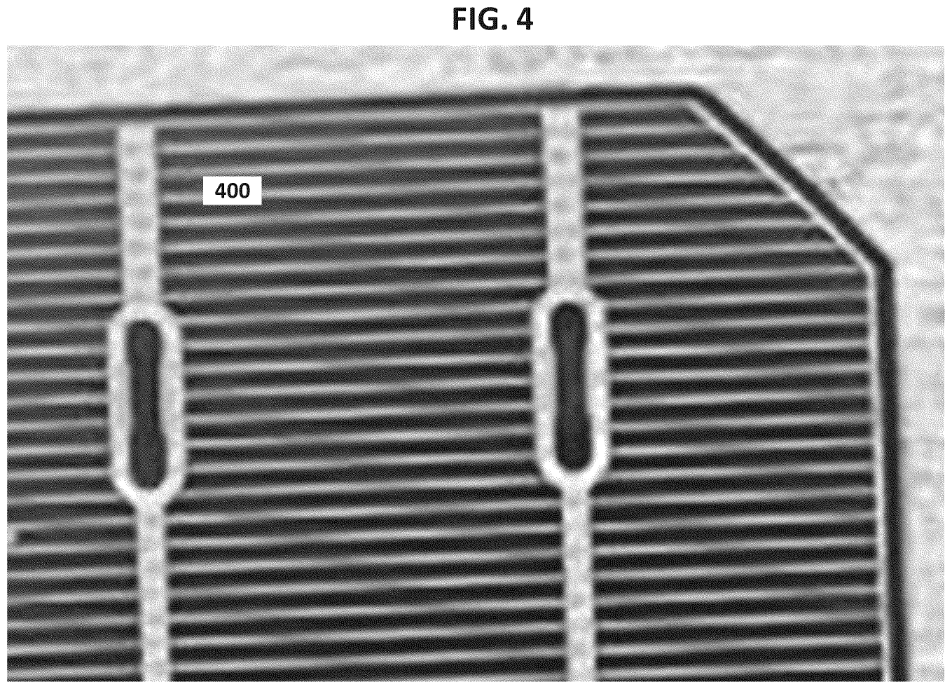

FIG. 4 shows the back side of a bifacial cell following exposure to sulfur. The back silver solder pads are appreciably darkened in color. The remaining aluminum metallization elements are substantially unchanged in appearance.

This disclosure is illustrative and not limiting. Further modifications will be apparent to one skilled in the art in light of this disclosure and are intended to fall within the scope of the appended claims. For example, where methods and steps described above indicate certain events occurring in certain order, those of ordinary skill in the art will recognize that the ordering of certain steps may be modified, and that some steps may be omitted or additional steps added, and that such modifications are in accordance with the variations of the invention.

What is claimed is:

1. A method comprising:
exposing a metallic component of a solar module to an environmental condition such that an appearance of the metallic component is darkened.

2. A method as in claim 1 wherein the environmental condition is in the liquid phase.

3. A method as in claim 1 wherein the environmental condition comprises sulfur.

4. A method as in claim 3 wherein the environmental condition comprises hydrogen sulfide.

5. A method as in claim 3 wherein the environmental condition comprises liver of sulfur.

6. A method as in claim 1 wherein the environmental condition comprises at least one of ozone, hydrogen peroxide, sulfur, and chlorine.

7. A method as in claim 1 wherein the environmental condition is in the gas phase.

8. A method as in claim 1 wherein the metallic component comprises silver.

9. A method as in claim 8 wherein the silver comprises a silver finger.

10. An apparatus comprising:
a solar module comprising a front surface including a dark photovoltaic material and a metallic component having a dark patina.

11. An apparatus as in claim 10 wherein the metallic component comprises silver.

12. An apparatus as in claim 11 wherein the dark patina comprises silver sulfide.

13. An apparatus as in claim 11 wherein the dark patina comprises silver oxide.

14. An apparatus as in claim 11 wherein the dark patina comprises silver chloride.

15. An apparatus as in claim 11 wherein the metallic component comprises a conductive finger.
